(19) United States
(12) Patent Application Publication
(10) Pub. No.: US 2024/0349534 A1
(43) Pub. Date: Oct. 17, 2024

(54) DISPLAY PANEL

(71) Applicant: Wuhan China Star Optoelectronics Semiconductor Display Technology Co., Ltd., Wuhan, Hubei (CN)

(72) Inventors: Tao CHEN, Wuhan, Hubei (CN); Songpo XIANG, Wuhan, Hubei (CN); Hao TANG, Wuhan, Hubei (CN)

(73) Assignee: Wuhan China Star Optoelectronics Semiconductor Display Technology Co., Ltd., Wuhan, Hubei (CN)

(21) Appl. No.: 17/615,120

(22) PCT Filed: Oct. 11, 2021
(86) PCT No.: PCT/CN2021/122988

§ 371 Date: Jun. 26, 2024

(30) Foreign Application Priority Data
Sep. 26, 2021 (CN) 202111127183.X

(51) Int. Cl. H10K 59/121; H10K 59/35

(52) U.S. Cl. CPC H10K 59/1213; H10K 59/353

(57) ABSTRACT

A display panel is provided in the present disclosure, wherein a plurality of centers of a plurality of second pixels in a same row are located on a line differing from a plurality of centers of a plurality of third pixels in a same row be located on, and/or a plurality of centers of the second pixels in a same column are located on a line differing from a plurality of centers of the third pixels in a same column be located on; a plurality of centers of a plurality of second through holes in a same row are located on a line differing from a plurality of centers of the third through holes in a same row be located on, and/or a plurality of centers of the second through holes in a same column are located on a line differing from a plurality of centers of the third through holes in a same column be located on. The display effect can be improved through the present disclosure.

### FIELD OF INVENTION

The present disclosure relates to the field of display technologies, and more particularly, to a display panel.

### BACKGROUND OF INVENTION

A traditional OLED display panel includes a plurality of pixels with different colors, and the plurality of pixels with different colors are arranged in an array.

In order to increase the aperture ratio, traditional technical solutions generally arrange the plurality of pixels with different colors in a regular shape. That is, in the smallest repeating unit of the pixels, a shape formed by a connecting line connecting centers of the plurality of the pixels is a regular shape (for example, a rectangle). There is a gap between the plurality of pixels with different colors, the gap separates the pixels with different colors, and the width of the gap between the pixels with different colors is equal.

In the abovementioned traditional technical solutions, in a pixel column or a pixel row including at least two pixels with different colors, the pixels with different colors are arranged along a straight line.

In practice, the inventor found that arranging the pixels with different colors along a straight line in the row direction or in the column direction is not conducive to further improving the display effect.

Therefore, it is necessary to provide a novel technical solution to solve the abovementioned problems of the prior art.

### SUMMARY OF INVENTION

### Technical Problem

The object of the present disclosure is to provide a display panel, which can improve the display effect.

### Solutions of the Technical Problem

### Technical Solution

In order to solve the abovementioned problems, technical solutions provided in the present disclosure as follow:

A display panel, comprising: a pixel-driving circuit arranged in an array; a plurality of light-emitting pixels including a plurality of first pixels, a plurality of second pixels, and a plurality of third pixels; and an insulating layer located between the pixel-driving circuit and the light-emitting pixels and provided with a plurality of first through holes, a plurality of second through holes, and a plurality of third through holes; wherein the first pixels, the second pixels, and the third pixels are electrically connected to the pixel-driving circuit via the first through holes, the second through holes, and the third through holes, respectively; wherein centers of the second pixels connected to the pixel-driving circuit in a same row are located in a line differing from a line in which centers of the third pixels connected to the pixel-driving circuit in a same row are located, and/or centers of the second pixels connected to the pixel-driving circuit in a same column are located in a line differing from a line in which centers of the third pixels connected to the pixel-driving circuit in a same column are located; wherein centers of the second through holes corresponding to the second pixels in a same row are located in a line differing from a line in which centers of the third through holes corresponding to the third pixels in a same row are located, and/or centers of the second through holes corresponding to the second pixels in a same column are located in a line differing from a line in which centers of the third through holes corresponding to the third pixels in a same column are located.

In the above display panel, a connecting line of the centers of the second through holes corresponding to the second pixels in the same row is parallel or intersecting with a connecting line of the centers of third through holes corresponding to the third pixels in the same row, and a connecting line of the centers of second holes corresponding to the second pixels in the same column is parallel or intersecting with a connecting line of the centers of third through holes corresponding to the third pixels in the same column.

In the above display panel, along one of a first direction and a second direction, the center of one of the second pixels is located outside a connecting line of the centers of the adjacent two third pixels, the center of one of the third pixels is located outside a connecting line of the centers of the adjacent two second pixels, the first direction is a direction in which the first pixels are repeatedly arranged, and the second direction is a direction perpendicular to the first direction; along the other one of the first direction and the second direction, a connecting line connecting the center of one of the second pixels and the center of the adjacent one of the third pixels is parallel to the other one of the first direction and the second direction.

In the above display panel, a shape of one of the first pixels is a rectangle, a shape of one of the second pixels is a square, a shape of one of the third pixels is a rectangle, a long edge of one of the first pixels is parallel to a long edge of one of the third pixels, and a short edge of one of the first pixels is parallel to one edge of one of the second pixels.

In the above display panel, a shape of one of the second pixels and a shape of one of the third pixels are both trapezoids, a shape of one of the first pixels is a rectangle, a long edge of one of the first pixels is parallel to a bottom edge of one of the second pixels whose shape is the trapezoid or a bottom edge of one of the third pixels whose shape is the trapezoid, and a short edge of one of the first pixels is parallel to the bottom edge of one of the third pixels whose shape is the trapezoid or the bottom edge of one of the second pixels whose shape is the trapezoid.

In the above display panel, a long edge of one of the first pixels is parallel to one edge of one of the second pixels whose shape is a parallelogram or one edge of one of the third pixels whose shape is a parallelogram, and a short edge of one of the first pixels is parallel to one edge of one of the third pixels whose shape is the parallelogram or one edge of one of the second pixels whose shape is the parallelogram.

In the above display panel, a shape of one of the first pixels includes a convex arc, and a shape of one of the second pixels and a shape of one of the third pixels both include a concave arc and/or a convex arc.

In the above display panel, a shape of one of the first pixels is a circle or an ellipse, a shape of one of the second pixels and a shape of one of the third pixels both include a plurality of concave arcs and a plurality of convex arcs, two ends of one of the convex arcs are respectively connected to two of the concave arcs, two ends of one of the concave arcs are respectively connected to two of the convex arcs, and an arc length of one of the convex arcs is less than an arc length of one of the concave arcs; wherein the arc length of the concave arc in the second pixel is greater or less than the arc length of the concave arc in the third pixel.

In the above display panel, one of the two second pixels adjacent to the first pixel has a curvature radius toward an edge portion of the first pixel, and the curvature radius is greater than or equal to a curvature radius of the other one of the two second pixels adjacent to the first pixel toward the edge portion of the first pixel; and one of the two third pixels adjacent to the first pixel has a curvature radius toward the edge portion of the first pixel, and the curvature radius is greater than or equal to a curvature radius of the other one of the two third pixels adjacent to the first pixel toward the edge portion of the first pixel.

In the above display panel, when the shape of the first pixel is an ellipse, a first included angle between a connecting line A1 connecting the centers of two of the second pixels adjacent to the first pixel and a long axis of the ellipse is greater than or equal to 0 degree, and is less than or equal to 90 degrees, and a second included angle between a connecting line A2 connecting the centers of two of the third pixels adjacent to the first pixel and the long axis of the ellipse is greater than or equal to 0 degree, and is less than or equal to 90 degrees.

In the above display panel, a curvature radius of one of at least four concave arcs constituting the shape of the second pixel is greater than a curvature radius of another one of the four concave arcs constituting the shape of the second pixel, or a curvature radius of one of at least four concave arcs constituting the shape of the third pixel is greater than a curvature radius of another one of the four concave arcs constituting the shape of the third pixel.

In the above display panel, a shape of one of the first pixels is a trapezoid, and a shape of one of the second pixels and a shape of one of the third pixels both include a plurality of concave arcs and/or a plurality of convex arcs.

In the above display panel, the centers of two of the second pixels and two of the third pixels adjacent to the first pixel are four vertices of a predetermined quadrilateral, the predetermined quadrilateral at least includes a first internal angle less than or equal to 90 degrees and a second internal angle greater than or equal to 90 degrees, and the predetermined quadrilateral is a trapezoid or a parallelogram.

In the above display panel, the angle of the first internal angle is in a range of 78 degrees to 88 degrees, and the angle of the second angle is in a range of 92 degrees to 102 degrees.

In the above display panel, a distance E1 between a connecting line connecting the centers of two of the second pixels and a connecting line connecting the centers of two of the third pixels is less than a distance E2 between a connecting line connecting the centers of two of the first pixels and a connecting line connecting the centers of two of the second pixels.

In the above display panel, a distance E1 between a connecting line connecting the centers of two of the second pixels and a connecting line connecting the centers of two of the third pixels is less than a distance E3 between a connecting line connecting the centers of two of the first pixels and a connecting line connecting the centers of two of the third pixels.

In the above display panel, an intersection of a connecting line connecting the centers of two of the second pixels adjacent to the first pixel and a connecting line connecting the centers of two of the third pixels adjacent to the first pixel is located within a range enclosed by a circle, wherein the center of the first pixel is served as a center of the circle and a predetermined line segment is served as the radius of the circle.

In the above display panel, a projection of the first pixel on a plane where the display panel is located covers the intersection.

In the above display panel, the centers of the first pixels are located outside a connecting line connecting the centers of two of the second pixels adjacent to the first pixel and/or outside a connecting line connecting the centers of two of the third pixels adjacent to the first pixel.

In the above display panel, a thickness of a luminescent material layer of one of the first pixel, the second pixel, and the third pixel which has a higher luminous efficiency is greater than a thickness of a luminescent material layer of one of the first pixel, the second pixel, and the third pixel which has a lower luminous efficiency.

### Advantageous Effects of the Present Disclosure

### Advantageous Effects

In the present disclosure, because the centers of the second pixels connected to the pixel-driving circuit in a same row are located in a line differing from a line in which the centers of the third pixels connected to the pixel-driving circuit in a same row are located, and/or the centers of the second pixels connected to the pixel-driving circuit in a same column are located in a line differing from a line in which the centers of the third pixels connected to the pixel-driving circuit in a same column are located; and the centers of the second through holes corresponding to the second pixels in a same row are located in a line differing from a line in which the centers of the third through holes corresponding to the third pixels in a same row are located, and/or the centers of the second through holes corresponding to the second pixels in a same column are located in a line differing from a line in which the centers of the third through holes corresponding to the third pixels in a same column are located, in at least one of the first direction and the second direction, at least two pixels with different colors are arranged along a polyline instead of being arranged along a straight line. Therefore, the pixels in adjacent two pixel rows can be merged in the column direction, or the pixels in adjacent two pixel columns can be merged in the row direction, which is beneficial to improving the display effect.

### BRIEF DESCRIPTION OF THE DRAWINGS

### Description of Drawings

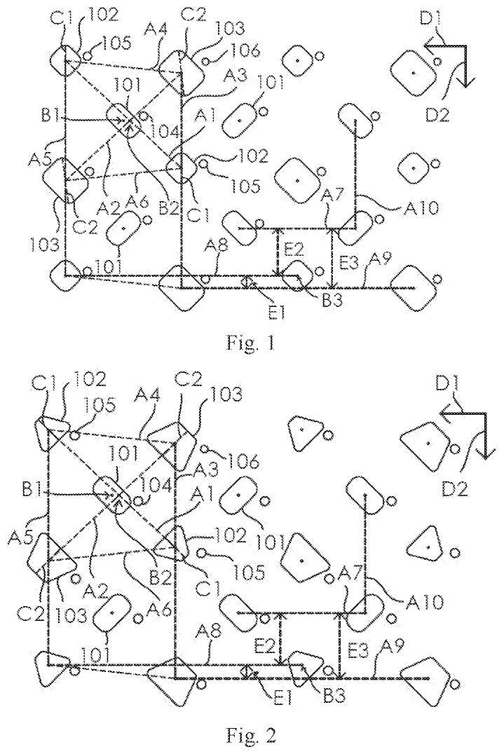

FIG. 1 is a schematic diagram of a first embodiment of the display panel in the present invention.

FIG. 2 is a schematic diagram of a second embodiment of the display panel in the present invention.

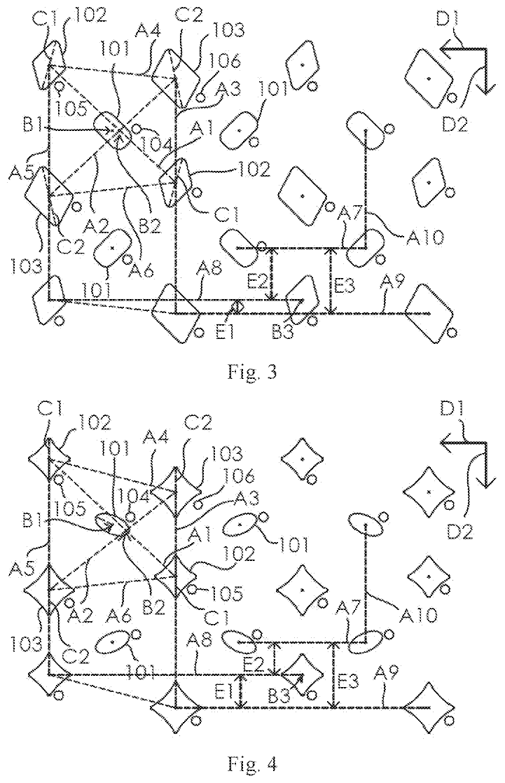

FIG. 3 is a schematic diagram of a third embodiment of the display panel in the present invention.

FIG. 4 is a schematic diagram of a fourth embodiment of the display panel in the present invention.

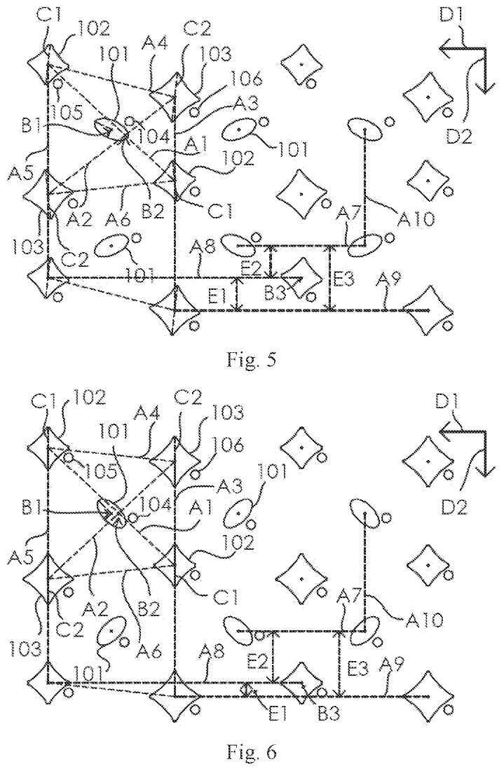

FIG. 5 is a schematic diagram of a fifth embodiment of the display panel in the present invention.

FIG. 6 is a schematic diagram of a sixth embodiment of the display panel in the present invention.

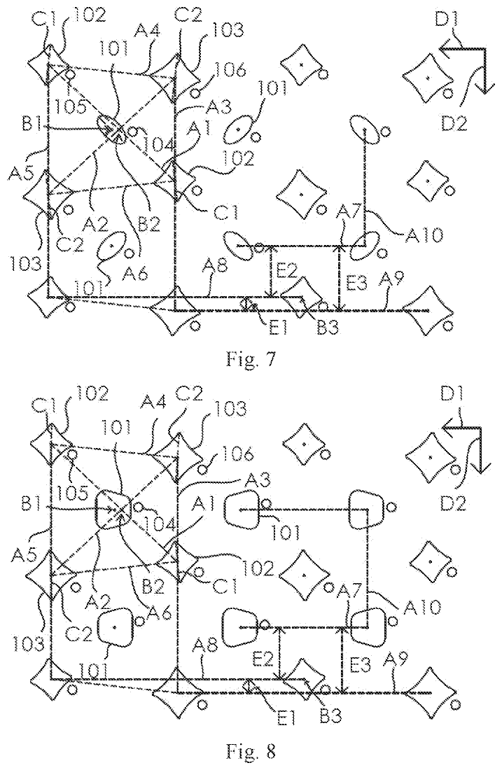

FIG. 7 is a schematic diagram of a seventh embodiment of the display panel in the present invention.

FIG. 8 is a schematic diagram of an eighth embodiment of the display panel in the present invention.

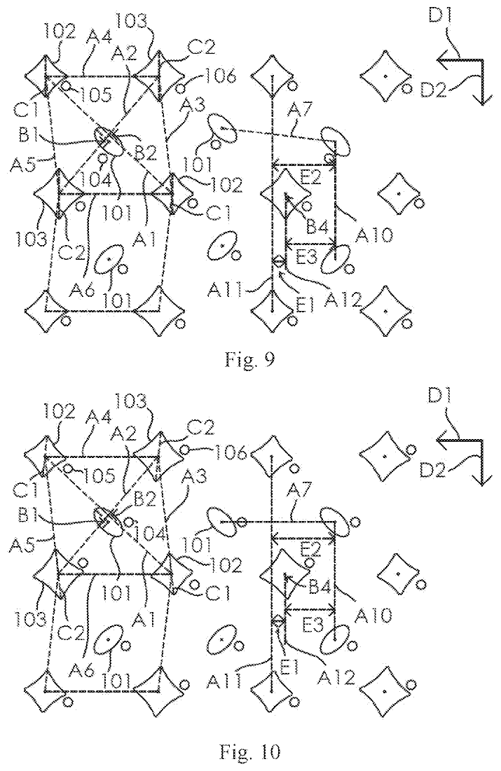

FIG. 9 is a schematic diagram of a ninth embodiment of the display panel in the present invention.

FIG. 10 is a schematic diagram of a tenth embodiment of the display panel in the present invention.

### EXAMPLES

### Detailed Description of Preferred Embodiments

The word “embodiment” used in this specification means an example, example, or illustration. In addition, the article “a” used in this specification and appended claims can generally be construed as “one or more” unless otherwise specified or the singular form can be clearly determined from the context.

Any two of the first embodiment to the tenth embodiment of the display panel of the present invention are similar or similar.

A display panel provided in the present disclosure may be, for example, an Organic Light Emitting Diode (OLED) display panel. The display panel includes a substrate, at least three pixel-driving circuits, an insulating layer, at least three light-emitting pixels, and an encapsulation layer. The pixel-driving circuits are disposed on the substrate, the insulating layer is disposed on the pixel-driving circuits, the light-emitting pixels are disposed on the insulating layer, and the encapsulation layer is disposed on the light-emitting pixels. At least six of the pixel-driving circuits are arranged in a two-dimensional array. The pixel-driving circuit includes scan lines, data lines, thin film transistors, and the like. The thin film transistor is connected to the scan line and the data line. At least six of the light-emitting pixels are arranged in a two-dimensional array. That is, the light-emitting pixel is disposed on the insulating layer, and the light-emitting pixel includes a light-emitting device, wherein the light-emitting device includes an anode layer, a luminescent material layer, and a cathode layer. The luminescent material layer is disposed between the anode layer and the cathode layer. The display panel further includes a pixel definition layer, and the pixel definition layer includes a retaining wall, at least a portion of the anode layer, at least a portion of the luminescent material layer, and at least a portion of the cathode layer disposed in an area defined by the retaining wall. The insulating layer is disposed between the pixel-driving circuit and the light-emitting pixel, that is, in a direction perpendicular to the plane where the substrate is located, the insulating layer is disposed between the thin film transistor and the light-emitting device. The insulating layer is provided with at least six through holes, one of the through holes corresponds to one of the light-emitting pixels and one of the pixel-driving circuits, and one of the light-emitting pixels is connected to one of the pixel-driving circuits via a conductive member disposed in one of the through holes. That is, the conductive member electrically connects the thin film transistor and the light-emitting device, and an area of an opening of the through hole is less than an area of the light-emitting device (light-emitting pixel). For example, as shown in FIG. 1 to FIG. 10, the area of the opening of the through holes (including first through holes 104, second through holes, and third through holes) is less than the area of the light-emitting pixels (including first pixels 101, second pixels 102, and third pixels 103). The encapsulation layer covers the light-emitting device. In the display panel, the least three through holes, which connect least three light-emitting pixels and at least three pixel-driving circuits, includes at least one first through hole 104, at least one second through hole 105, and at least one through hole 106. The first through hole 104 is a through hole corresponding to the first pixel 101, the second through hole 105 is a through hole corresponding to the second pixel 102, and the third through hole 106 is a through hole corresponding to the third pixel 103.

As shown in FIG. 1 to FIG. 10, the at least six of the light-emitting pixels include at least two first pixels 101, at least two second pixels 102, and at least third pixels 103, wherein one of the first pixels 101 is located between the two second pixels 102, the other one of the first pixels 101 is located between the two third pixels 103, and there is a gap between the first pixel 101, the second pixel 102, and the third pixel 103.

The at least six of the light-emitting pixels include at least two first pixel columns, at least second pixel columns, and at least third pixel columns. The first pixel column includes at least two of the first pixels 101 arranged along a column direction (for example, a second direction), and the first pixel column is located between the second pixel column and the third pixel column. The second pixel column includes at least two of the second pixels 102 and at least two of the third pixels 103 arranged along a column direction, and the second pixel column is located between the two first pixel columns. The third pixel column includes the at least two third pixels 103 and the at least two third pixels 103 arranged along a column direction, and the third pixel column is located between the two first pixel columns.

In the second pixel column, one of the second pixels 102 is located between two of the third pixels 103, and one of the third pixels 103 is located between two of the second pixels 102. In the third pixel column, one of the second pixels 102 is located between two of the third pixels 103, and one of the third pixels 103 is located between two of the second pixels 102.

Along a second direction D2 (for example, a column direction) perpendicular to a first direction D1 (for example, a row direction), the second pixels 102 and the third pixels 103 in the second pixel column are alternately arranged with the first pixels 101 in the first pixel column, and the second pixels 102, the third pixels 103 in the third pixel column are alternately arranged with the first pixels 101 in the first pixel column. The second pixels 102 in the second pixel column and the second pixels 102 in the third pixel column are arranged alternately, and the third pixels 103 in the second pixel column and the third pixels 103 in the third pixel column are arranged alternately.

A through hole corresponding to the light-emitting pixel with one color is located outside a connecting line of through holes corresponding to two light-emitting pixels with another color. The first through hole 104 corresponding to the first pixels 101 is located outside a connecting line of the second through holes 105 corresponding to the two second pixels 102 arranged along the first direction D1 or along the second direction D2, and/or, the first through hole 104 corresponding to the first pixel 101 is located outside a connecting line of the third through holes 106 corresponding to the two third pixels 103 arranged along the first direction D1 or along the second direction D2, wherein the first direction D1 is a direction in which the first pixels are repeatedly arranged, and the second direction D2 is a direction perpendicular to the first direction.

The center of the light-emitting pixel with one color is located outside a connecting line of the centers of the two light-emitting pixels with another color. That is, the centers of the three different color light-emitting pixels driven by a pixel-driving circuit connected to a light-emitting pixel raw are located in different lines, or the centers of the light-emitting pixels, which have different colors, driven by a pixel-driving circuit connected to a light-emitting pixel column are located in different lines. Along one of the first direction D1 and the second direction D2, the center of one of the second pixels 102 is located outside a connecting line of the centers of the adjacent two third pixels 103, the center of one of the third pixels 103 is located outside a connecting line of the centers of the adjacent two second pixels 102. Along the other one of the first direction D1 and the second direction D2, a connecting line connecting the center of one of the second pixels 102 and the center of the adjacent one of the third pixels 103 is parallel to the other one of the first direction D1 and the second direction D2. That is, along the first direction D1, the center B3 of the second pixels 102 is located outside a connecting line of the centers A9 of the adjacent two third pixels 103, the center B4 of the third pixels 103 is located outside a connecting line of the centers A11 of the adjacent two second pixels 102, and along the second direction D2, a connecting line connecting the center of the second pixels 102 and the center of the adjacent third pixels 103 is parallel to the second direction D2. Alternatively, along the first direction D1, a connecting line connecting the center of the second pixels 102 and the center of the adjacent third pixels 103 is parallel to the second direction D1, and along the second direction D2, the center B3 of the second pixels 102 is located outside a connecting line A9 of the adjacent two third pixels 103, and the center B4 of the third pixels 103 is located outside a connecting line A11 of the adjacent two second pixels 102.

A connecting line of the second through holes 105 corresponding to the two second pixels 102 arranged along the first direction D1 or the second direction D2 and a connecting line of the third through holes 106 corresponding to the two third pixels 103 arranged along the first direction D1 or the second direction D2 are collinear, or a connecting line of the second through holes 105 corresponding to the two second pixels 102 arranged along the first direction D1 or the second direction D2 and a connecting line of the third through holes 106 corresponding to the two third pixels 103 arranged along the first direction D1 or the second direction D2 are intersecting.

A distance E1 between a connecting line A8 connecting the centers of two of the second pixels 102 and a connecting line A9 connecting the centers of two of the third pixels 103 is less than a distance E2 between a connecting line A7 connecting the centers of two of the first pixels 101 and a connecting line A8 connecting the centers of two of the second pixels 102, and/or, a distance E1 between a connecting line A8 connecting the centers of two of the second pixels 102 and a connecting line A9 connecting the centers of two of the third pixels 103 is less than a distance E3 between a connecting line A7 connecting the centers of two of the first pixels 101 and a connecting line A9 connecting the centers of two of the third pixels 103. That is, along the first direction D1, the distance E1 from the connecting line A8 connecting the centers of two of the second pixels 102 to the connecting line A9 connecting the centers of two of the third pixels 103 is less than the distance E2 form the connecting line A7 connecting the centers of two of the first pixels 101 to the connecting line A8 connecting the centers of two of the second pixels 102, or less than the distance E3 form the connecting line A7 to the connecting line A9 connecting the centers of two of the third pixels 103. Alternatively, along the second direction D2, the distance E1 from the connecting line A11 connecting the centers of two of the second pixels 102 to the connecting line A12 connecting the centers of two of the third pixels 103 is less than the distance E2 form the connecting line A10 connecting the centers of two of the first pixels 101 to the connecting line A11 connecting the centers of two of the second pixels 102, or less than the distance E3 form the connecting line A10 to the connecting line A12 connecting the centers of two of the third pixels 103. In a preferred embodiment, 3E1<E2<E3, through such a configuration, the regularity of the arrangement of light-emitting pixels is disrupted, so that the diffraction effect of the plurality of pixels with gaps in a strong light environment is weakened. Moreover, the sharpness of the edge of the displayed text can be continuously changed within the range that human eyes can recognize, and the strokes of the displayed text in certain directions can be prevented from appearing grainy or color shift.

Alternately, the through holes corresponding to at least three of the light-emitting pixels with the same color arranged along the first direction D1 or the second direction D2 are located on at least two intersecting lines. That is, at least three of the first through holes 104 corresponding to at least three of the first pixels 101 arranged along the first direction D1 or the second direction D2 are located on at least two intersecting lines, or at least three of the second through holes 105 corresponding to at least three of the second pixels 102 arranged along the first direction D1 or the second direction D2 are located on at least two intersecting lines, or at least three of the third through holes 106 corresponding to at least three of the third pixels 103 arranged along the first direction D1 or the second direction D2 are located on at least two intersecting lines.

Alternatively, an included angle between the connecting line of the through holes corresponding to one of the first pixel 101, the second pixel 102, and the third pixel 103 and the first direction D1 or the second direction D2 is greater than 0 degree and less than 90 degrees.

The display panel includes at least two first pixel rows, at least two second pixel rows, and at least two third pixel rows, wherein the first pixel row is located between the second pixel row and the third pixel row, the second pixel row is located between the two first pixel rows, and the third pixel row is located between the two first pixel rows.

The first pixel row includes at least two of the first pixels 101 arranged along a row direction, the second pixel row includes at least two of the second pixels 102 and at least two of the third pixels 103 arranged along the row direction, and the third pixel row includes at least two of the second pixels 102 and at least two of the third pixels 103 arranged along the row direction.

In the second pixel row, one of the second pixels 102 is located between two of the third pixels 103, and one of the third pixels 103 is located between two of the second pixels 102. In the third pixel row, one of the second pixels 102 is located between two of the third pixels 103, and one of the third pixels 103 is located between two of the second pixels 102. Along the row direction (for example, the first direction D1), the first pixels 101 in the first pixel row are alternately arranged with the second pixels 102 and the third pixels 103 in the second pixel row, the first pixels 101 in the first pixel row are alternately arranged with the second pixels 102 and the third pixels 103 in the third pixel row. The second pixel 102 in the second pixel row and the second pixel 102 in the third pixel row are arranged alternately, and the third pixel 103 in the second pixel row and the third pixel 103 in the third pixel row are arranged alternately.

At least two of the first pixel columns are arranged along a direction (for example, the first direction D1) perpendicular to the column direction (for example, the second direction D2), at least two of the second pixel columns are arranged along a direction perpendicular to the column direction, and at least two of the third pixel columns are arranged along a direction perpendicular to the column direction. At least two of the first pixel rows are arranged along a direction perpendicular to the row direction, at least two of the second pixel rows are arranged along a direction (for example, the second direction D2) perpendicular to the row direction (for example, the first direction D1), and at least two of the third pixel rows are arranged along a direction perpendicular to the row direction.

The display panel includes at least two minimum repeating units, and the minimum repeating unit includes at least one of the first pixels 101, at least one of the second pixels 102, and at least one of the third pixels 103. A total area of all the first pixels 101 in the minimum repeating unit (for example, the area of one first pixel 101, the sum of the area of two first pixels 101), a total area of all the second pixels 102 (for example, the area of one second pixel 102, the sum of the areas of two the second pixels 102), a total area of all the third pixels 103 (for example, the area of one third pixel 103, the sum of the areas of two third pixels 103) are respectively inversely proportional to a luminous efficiency of the luminescent material of the first pixel 101, a luminous efficiency of the luminescent material of the second pixel 102, and a luminous efficiency of the luminescent material of the third pixel 103.

The first pixel 101, the second pixel 102, and the third pixel 103 are different ones of a red pixel, a green pixel, and a blue pixel. Preferably, the first pixel 101 is a green pixel, the second pixel 102 is one of a red pixel and a blue pixel, and the third pixel 103 is the other one of a red pixel and a blue pixel. The shape, the size, and the area of any two of the first pixel 101, the second pixel 102, and the third pixel 103 are different.

A shape of the first pixel 101, a shape of the second pixel 102, and a shape of the third pixel 103 are one of a rectangle, a parallelogram, and a trapezoid. Preferably, the rectangle is a rectangle with rounded corners (that is, the rectangle is an approximate rectangle or a substantially rectangle, the corners of the rectangle are rounded corners, and the four straight edges of the rounded rectangle and its extension lines constitute a standard rectangle), as shown in FIG. 1. The parallelogram is a parallelogram with rounded corners (that is, the parallelogram is an approximate parallelogram or a substantially parallelogram, the corners of the parallelogram are rounded corners, and the four straight edges of the parallelogram with rounded corners and its extension lines constitute a standard parallelogram) as shown in FIG. 3. The trapezoid is a trapezoid with rounded corners (that is, the trapezoid is an approximately trapezoid or an substantially trapezoid, the corners of the trapezoid are rounded corners, and the four straight edges of the trapezoid with rounded corners and its extension lines constitute a standard trapezoid), as shown in FIG. 2. The shape of the first pixel 101, the shape of the second pixel 102, and the shape of the third pixel 103 all includes straight lines and convex arcs, wherein two ends of one of the convex arcs are respectively connected to two of the straight lines, at least four of the straight lines and at least four of the convex arcs constitute the rectangle with rounded corners, the parallelogram with rounded corners, and the trapezoid with rounded corners. Preferably, the shape the first pixel 101 is a rectangle (a rectangle with rounded corners), the shape of the second pixel 102 is a square (a square with rounded corners), the shape of the third pixel 103 is a rectangle (a rectangle with rounded corners), a long edge of the first pixel 101 is parallel to a long edge of the third pixel 103, and a short edge of the first pixel 101 is parallel to one edge of the second pixel 102, as shown in FIG. 1. Alternatively, The shape of the second pixel 102 and the shape of the third pixel 103 are both trapezoids (trapezoids with rounded corners), for example, isosceles trapezoids (isosceles trapezoids with rounded corners), the first pixel 101 is a rectangle (a rectangle with rounded corners), a long edge of the first pixel 101 is parallel to a bottom edge of the second pixel 102 whose shape is the trapezoid or a bottom edge of the third pixel 103 whose shape is the trapezoid, and a short edge of the first pixel 101 is parallel to the bottom edge of the third pixel 103 whose shape is the trapezoid or the bottom edge of the second pixel 102 whose shape is the trapezoid, as shown in FIG. 2. Alternatively, a long edge of the first pixel 101 is parallel to one edge of the second pixel 102 whose shape is a parallelogram or one edge of the third pixel 103 whose shape is a parallelogram, and a short edge of the first pixel 101 is parallel to one edge of the third pixel 103 whose shape is the parallelogram or one edge of the second pixel 102 whose shape is the parallelogram, as shown in FIG. 3.

A shape of the first pixel 101 includes a convex arc, and a shape of the second pixel 102 and a shape of the third pixel 103 both include a concave arc and/or a convex arc, as shown in FIG. 4, FIG. 5, FIG. 6, FIG. 7, FIG. 8, FIG. 9, and FIG. 10. For example, the shape of the first pixel 101 includes a convex arc, the shape of the second pixel 102 and the shape of the third pixel 103 both include a concave arc and a convex arc, or the shape of the second pixel 102 and the shape of the third pixel 103 both include a concave arc. Alternatively, the shape of the second pixel 102 includes a concave arc and a convex arc, and the shape of the third pixel 103 includes a concave arc. The shape including the convex arc is a regular circle or a regular ellipse, or an irregular shape that is roughly similar or roughly similar to a circle, or an irregular shape that is roughly similar or roughly similar to an ellipse.

Preferably, a shape of the first pixel 101 is a circle or an ellipse, a shape of the second pixel 102 and a shape of the third pixel 103 both include a plurality of concave arcs and a plurality of convex arcs, two ends of one of the convex arcs are respectively connected to two of the concave arcs, two ends of one of the concave arcs are respectively connected to two of the convex arcs, and an arc length of one of the convex arcs is less than an arc length of one of the concave arc. The arc length of the concave arc in the second pixel 102 is greater or less than the arc length of the concave arc in the third pixel 103.

A shape of the first pixel 101 is a trapezoid, and a shape of the second pixel 102 and a shape of the third pixel 103 both include a plurality of concave arcs and/or a plurality of convex arcs, as shown in FIG. 8. Preferably, the distance between the top edge of the first pixel 101 which is trapezoidal and the connecting line A3, the distance between the bottom edge of the first pixel 101 which is trapezoidal and the connecting line A5, the distance between the edge (waist), close to the connecting line A4, of the first pixel 101 which is trapezoidal and the connecting line A4, and the distance between the edge (waist), close to the connecting line A6, of the first pixel 101 which is trapezoidal and the connecting line A6 are equal. Among the four convex arcs corresponding to the four rounded corners of the first pixel 101 which is trapezoidal, a curvature radius of one of the adjacent two convex arcs is greater or less than a curvature radius of the other one of the adjacent two convex arcs. The distance between a rounded edge portion (convex arc) of the first pixel 101 toward the adjacent second pixel 102 and an edge portion (concave arc) of the second pixel 102 toward the first pixel 101 is equal to the distance between a rounded edge portion (convex arc) of the first pixel 101 toward the adjacent third pixel 103 and an edge portion (concave arc) of the third pixel 103 toward the first pixel 101.

The centers of two of the second pixels 102 and two of the third pixels 102 adjacent to the first pixel 101 are four vertices of a predetermined quadrilateral, the predetermined quadrilateral at least includes a first internal angle less than or equal to 90 degrees and a second internal angle greater than or equal to 90 degrees. The second internal angle is an internal angle adjacent to the first internal angle, and the angle of the first internal angle is in a range of 78 degrees to 88 degrees, and the angle of the second angle is in a range of 92 degrees to 102 degrees. For example, the angle of the first internal angle is 78 degrees, 79 degrees, 80 degrees, 81 degrees, 82 degrees, 83 degrees, 84 degrees, 85 degrees, 86 degrees, 87 degrees, or 88 degrees, and the angles of the second internal angles are 92 degrees, 93 degrees, 94 degrees, 95 degrees, 96 degrees, 97 degrees, 98 degrees, 99 degrees, 100 degrees, 101 degrees, or 102 degrees. The predetermined quadrilateral includes an irregular quadrilateral or a regular quadrilateral, and the regular quadrilateral may be, for example, a trapezoid or a parallelogram (as shown in FIG. 9 and FIG. 10). The trapezoid is a non-isosceles trapezoid (as shown in FIG. 4 and FIG. 5) or an isosceles trapezoid (as shown in FIG. 1, FIG. 2, FIG. 3, FIG. 6, FIG. 7, and FIG. 8).

The shape of the edge of the first pixel 101 is complementary to the shape of the edge of the adjacent second pixel 102, and the shape of the edge of the first pixel 101 is complementary to the shape of the edge of the adjacent third pixel 103. The term “complementary” means that the two shapes include a convex shape and a concave shape, respectively, and when the two shapes move towards each other and come into contact with each other, the two shapes match, fit or contain each other.

Specifically, the shape of the edge portion of the first pixel 101 toward the second pixel 102 and the shape of the edge portion of the adjacent second pixel 102 toward the first pixel 101 are a convex shape and a concave shape, respectively, and the convex shape and the concave shape are matched, fitted or contain with each other in size. The shape of the edge portion of the first pixel 101 toward the third pixel 103 and the shape of the edge portion of the adjacent third pixel 103 toward the first pixel 101 are a convex shape and a concave shape, respectively, and the convex shape and the concave shape are matched, fitted or contain with each other in size.

In the case where the predetermined quadrilateral is a parallelogram, the first pixel 101 is an ellipse, the shape of the second pixel 102 and the shape of the third pixel 103 include concave arcs, a long axis of the first pixel 101 which is an ellipse is parallel to a longer diagonal of the parallelogram.

In the case where the predetermined quadrilateral is an irregular quadrilateral, the first pixel 101 is an ellipse, and the shape of the second pixel 102 and the shape of the third pixel 103 include concave arcs, the midpoint of the line A3 and the midpoint of the line A5 are located on the extended line of the long axis of the first pixel 101 which is an ellipse.

An intersection B2 of a connecting line A1 connecting the centers of two of the second pixels 102 adjacent to the first pixel 101 and a connecting line A2 connecting the centers of two of the third pixels 103 adjacent to the first pixel 101 is located within a range enclosed by a circle, wherein the center B1 of the first pixel 101 is served as a center of the circle and a predetermined line segment (for example, the long axis of the first pixel which is an ellipse) is served as the radius of the circle.

In particular, ah shown in FIG. 1 to FIG. 10, the intersection B2 of the connecting line A1 connecting the centers of two of the second pixels 102 adjacent to the first pixel 101 and the connecting line A2 connecting the centers of two of the third pixels 103 adjacent to the first pixel 101 is located within range enclosed by the edge line of the first pixel 101. In other words, a projection of the first pixel 101 on a plane where the display panel is located covers the intersection B2. In one case, the intersection B2 overlaps the center B1 of the first pixel 101, and in the other case, the intersection B2 does not overlap the center B1 of the first pixel 101,

The centers B1 of the first pixels 101 are located outside a connecting line A1 connecting the centers of two of the second pixels 102 adjacent to the first pixel 101 and/or outside a connecting line A2 connecting the centers of two of the third pixels 103 adjacent to the first pixel 101. That is, the intersection B2 does not overlap the center B1 of the first pixel 101.

A curvature radius of one of the second pixel 102 and the third pixel 103 adjacent to the first pixel 101 is greater than or equal to a curvature radius of the other one of the second pixel 102 and the third pixel 103 adjacent to the first pixel 101 toward the edge portion of the first pixel 101.

One of the two second pixels 102 adjacent to the first pixel 101 has a curvature radius toward an edge portion of the first pixel 101, and the curvature radius is greater than or equal to a curvature radius of the other one of the two second pixels 102 adjacent to the first pixel toward the edge portion of the first pixel 101, and one of the two third pixels 103 adjacent to the first pixel 101 has a curvature radius toward the edge portion of the first pixel 101, and the curvature radius is greater than or equal to a curvature radius of the other one of the two third pixels 103 adjacent to the first pixel 101 toward the edge portion of the first pixel 101.

The width of a gap between the first pixel 101 and the second pixel 102 is greater or less than the width of a gap between the first pixel 101 and the third pixel 103. Alternatively, the width of the gap between the first pixel 101 and the second pixel 102 is equal to the width of the gap between the first pixel 101 and the third pixel 103.

The arc corresponding to the edge portion of the third pixel 103 toward the first pixel 101 and extended arc thereof and the arc corresponding to the edge portion of the second pixel 102 toward the first pixel 101 and extended arc thereof constitute a predetermined shape. The predetermined shape is a circle, an ellipse, a trapezoid with rounded corners, a parallelogram with rounded corners, or a rectangle with rounded corners. The shape of the first pixel 101 is the same or similar to the predetermined shape. The center of the shape of the first pixel 101 is the same as the center of the predetermined shape.

In the case where the shape of the first pixel 101 is an ellipse, a ratio of the long axis to the short axis of the ellipse is in the range of 1 to 5. For example, the ratio is one of 1, 1.3, 1.6, 1.8, 2, 2.3, 2.5, 2.8, 3, 3.3, 3.5, 3.8, 4, 4.3, 4.5, 4.8, and 5. Preferably, the ratio of the long axis to the short axis of the ellipse is in the range of 1 to 3.

When the shape of the first pixel 101 is an ellipse, the long axis of the ellipse points to one of the second pixel 102 and the third pixel 103 adjacent to the first pixel 101, the short axis of the ellipse points to the other one of the second pixel 102 and the third pixel 103 adjacent to the first pixel 101. Specifically, the long axis of the first pixel 101 points to one of the second pixel 102 and the third pixel 103 which has a smaller area. The short axis of the first pixel 101 points to one of the second pixel 102 and the third pixel 103 which has a greater area.

For example, the long axis of the ellipse corresponding to the shape of the first pixel 101 points to the second pixel 102, and the short axis of the ellipse corresponding to the shape of the first pixel 101 points to the third pixel 103, correspondingly.

A first included angle between a connecting line A1 connecting the centers of two of the second pixels 102 adjacent to the first pixel 101 and a long axis of the ellipse is greater than or equal to 0 degree, and is less than or equal to 90 degrees.

A second included angle between a connecting line A2 connecting the centers of two of the third pixels 103 adjacent to the first pixel 101 and the long axis of the ellipse is greater than or equal to 0 degree, and is less than or equal to 90 degrees.

A third included angle between the connecting line A1 connecting the centers of two of the second pixels 102 adjacent to the first pixel 101 and the connecting line A2 connecting the centers of two of the third pixels 103 adjacent to the first pixel 101 is greater than 0 degree, and is less than or equal to 90 degrees.

A curvature radius of one of at least four concave arcs constituting the shape of the second pixel 102 is greater than a curvature radius of another (adjacent) one of the four concave arcs constituting the shape of the second pixel 102. That is, the curvature radius of two of the at least four concave arcs of the second pixel 102 are not equal. Alternatively, the curvature radius of two of at least four concave arcs constituting the shape of the second pixel 102 are equal. That is, the curvature radius of two of the at least four concave arcs of the second pixel 102 are equal.

Similarly, a curvature radius of one of at least four concave arcs constituting the shape of the third pixel 103 is greater than a curvature radius of another (adjacent) one of the four concave arcs constituting the shape of the third pixel 103. That is, the curvature radius of two of the at least four concave arcs of the third pixel 103 are not equal. Alternatively, the curvature radius of two of at least four concave arcs constituting the shape of the third pixel 103 are equal. That is, the curvature radius of two of the at least four concave arcs of the third pixel 103 are equal.

The area of one of the two second pixels 102 adjacent to the first pixel 101 is greater than or equal to the area of the other one of the two second pixels 102. That is, the areas of the two second pixels 102 adjacent to the first pixel 101 may not be equal. The area of one of the two third pixels 103 adjacent to the first pixel 101 is greater than or equal to the area of the other one of the two third pixels 103. That is, the areas of the two third pixels 103 adjacent to the first pixel 101 may not be equal.

There is a fourth included angle between a symmetry axis C1 of the second pixel 102 and the first direction D1 or the second direction D2, and the fourth included angle is greater than or equal to 0 degrees and is less than or equal to 90 degrees. There is a fifth included angle between a symmetry axis C2 of the third pixel 103 and the first direction D1 or the second direction D2, and the fifth included angle is greater than or equal to 0 degrees and is less than or equal to 90 degrees. As shown in FIG. 1, FIG. 4, FIG. 6, and FIG. 9, the fourth included angle between the symmetry axis C1 of the second pixel 102 and the second direction D2 is 0 degrees, and as shown in FIG. 2, FIG. 3, FIG. 5, FIG. 7, and FIG. 9, the fourth included angle between the symmetry axis C1 of the second pixel 102 and the second direction D2 is greater than 0 degrees. As shown in FIG. 4, FIG. 6, and FIG. 9, the fifth included angle between the symmetry axis C2 of the third pixel 103 and the second direction D2 is 0 degrees, and as shown in FIG. 1, FIG. 2, FIG. 3, FIG. 5, FIG. 7, FIG. 8, and FIG. 10, the fifth included angle between the symmetry axis C2 of the third pixel 103 and the second direction D2 is greater than 0 degrees.

There is a sixth included angle between the symmetry axis C1 of the second pixel 102 and the symmetry axis C2 of the third pixel 103, and the sixth included angle is greater than or equal to 0 degrees and is less than or equal to 90 degrees. As shown in FIG. 4, FIG. 6, FIG. 8, and FIG. 9, the sixth included angle is 0 degrees, and as shown in FIG. 1, FIG. 2, FIG. 3, FIG. 4, FIG. 5, FIG. 7, FIG. 8, and FIG. 10, the sixth included angle is greater than 0 degrees.

At least four of the first pixels 101 are arranged in a two-dimensional array along the first direction D1 and the second direction D2 perpendicular to the first direction D1. In the first direction D1, the orientations of the long axes of two adjacent first pixels 101 are different, that is, the long axes of two adjacent first pixels 101 are not parallel. In the second direction D2, the orientations of the long axes of two adjacent first pixels 101 are the same, that is, the long axes of two adjacent first pixels 101 are parallel. Along the first direction D1, there is a seventh included angle between the connecting line A7 connecting the centers B1 of two adjacent first pixels 101 and the first direction D1, and the seventh included angle is greater than or equal to 0 degrees and is less than 90 degrees. As shown in FIGS. 1 to 8, and FIG. 10, the seventh included angle is 0 degrees, and as shown in FIG. 9, the seventh included angle is greater than 0 degrees. Along the second direction D2, the connecting line A10 connecting the centers B1 of two adjacent first pixels 101 is parallel to the second direction D2. Alternatively, along the second direction D2, there is an eighth included angle between the connecting line A10 connecting the centers B1 of two adjacent first pixels 101 and the second direction D2, and the eighth included angle is greater than or equal to 0 degrees and is less than 90 degrees. As shown in FIGS. 1 to 8, the eighth included angle is greater than 0 degrees, and as shown in FIG. 9 and FIG. 10, the eighth included angle is 0 degrees. Along the first direction D1, the connecting line A7 connecting the centers B1 of two adjacent first pixels 101 is parallel to the first direction D1.

Along the first direction D1, one of the second pixels 102 is located between two of the third pixels 103, and one of third pixels 103 is located between two of the second pixels 102. Along the second direction D2, one of the second pixels 102 is located between two of the third pixels 103, and one of the third pixels 103 is located between two of the second pixels 102.

At least four of the second pixels 102 are arranged in a two-dimensional array along the first direction D1 and the second direction D2, and at least four of the third pixels 103 are arranged in a two-dimensional array along the first direction D1 and the second direction D2.

The distance between the center B3 of the second pixel 102 and the connecting line A9 is less than or equal to the distance between the center B3 of the second pixel 102 and the center of the first pixel 101. Preferably, the distance between the center B3 of the second pixel 102 and the connecting line A9 is less than or equal to the width of the gap between the second pixel 102 and the first pixel 101.

The distance between the center B4 of the third pixel 103 and the connecting line A10 is less than or equal to the distance between the center B4 of the third pixel 103 and the center of the first pixel 101. Preferably, the distance between the center B4 of the third pixel 103 and the connecting line A10 is less than or equal to the width of the gap between the third pixel 103 and the first pixel 101.

The first included angle, the second included angle, the fourth included angle, the fifth included angle, the sixth included angle, the seventh included angle, and the eighth included angle may be, for example, 0 degree, 1 degree, 2 degree, 3 degree, 4 degree, 5 degree, 6 degree, 7 degree, 8 degree, 9 degree, 10 degree, 11 degree, 12 degree, 13 degree, 14 degree, 15 degree, 16 Degrees, 17 degrees, 18 degrees, 19 degrees, 20 degrees, 21 degrees, 22 degrees, 23 degrees, 24 degrees, 25 degrees, 26 degrees, 27 degrees, 28 degrees, 29 degrees, 30 degrees, 31 degrees, 32 degrees, 33 degrees, 34 degrees, 35 degrees, 36 degrees, 37 degrees, 38 degrees, 39 degrees, 40 degrees, 41 degrees, 42 degrees, 43 degrees, 44 degrees, 45 degrees, 46 degrees, 47 degrees, 48 degrees, 49 degrees, 50 degrees, 51 degrees, 52 degrees, 53 degrees, 54 degrees, 55 degrees, 56 degrees, 57 degrees, 58 degrees, 59 degrees, 60 degrees, 61 degrees, 62 degrees, 63 degrees, 64 degrees, 65 degrees, 66 degrees, 67 degrees, 68 degrees, 69 degrees, 70 degrees, 71 degrees, 72 degrees, 73 degrees, 74 degrees, 75 degrees, 76 degrees, 77 degrees, 78 degrees, 79 degrees, 80 degrees, 81 degrees, 82 degrees, 83 degrees, 84 degrees, 85 degrees, 86 degrees, 87 degrees, 88 degrees, 89 degrees, or 90 degrees.

The third included angle may be, for example, 1 degree, 2 degree, 3 degree, 4 degree, 5 degree, 6 degree, 7 degree, 8 degree, 9 degree, 10 degree, 11 degree, 12 degree, 13 degree, 14 degree, 15 degree, 16 Degrees, 17 degrees, 18 degrees, 19 degrees, 20 degrees, 21 degrees, 22 degrees, 23 degrees, 24 degrees, 25 degrees, 26 degrees, 27 degrees, 28 degrees, 29 degrees, 30 degrees, 31 degrees, 32 degrees, 33 degrees, 34 degrees, 35 degrees, 36 degrees, 37 degrees, 38 degrees, 39 degrees, 40 degrees, 41 degrees, 42 degrees, 43 degrees, 44 degrees, 45 degrees, 46 degrees, 47 degrees, 48 degrees, 49 degrees, 50 degrees, 51 degrees, 52 degrees, 53 degrees, 54 degrees, 55 degrees, 56 degrees, 57 degrees, 58 degrees, 59 degrees, 60 degrees, 61 degrees, 62 degrees, 63 degrees, 64 degrees, 65 degrees, 66 degrees, 67 degrees, 68 degrees, 69 degrees, 70 degrees, 71 degrees, 72 degrees, 73 degrees, 74 degrees, 75 degrees, 76 degrees, 77 degrees, 78 degrees, 79 degrees, 80 degrees, 81 degrees, 82 degrees, 83 degrees, 84 degrees, 85 degrees, 86 degrees, 87 degrees, 88 degrees, 89 degrees, or 90 degrees.

In the second direction D2, there is a first distance value between the center of the second pixel 102 and the center of the closer one of the two adjacent third pixels 103, and there is a second distance value between the center of the second pixel 102 and the center of the farther one of the two adjacent third pixels 10. In addition, the center of the third pixel 103 and the center of the closer one of the two adjacent second pixels 102 have the first distance value, and the center of the third pixel 103 and the center of the farther one of the two adjacent second pixels 102 have the second distance value. The ratio of the first distance value to the second distance value is greater than or equal to 0.1 and is less than 1. For example, the ratio is 0.1, 0.13, 0.17, 0.2, 0.23, 0.26, 0.3, 0.34, 0.37, 0.4, 0.44, 0.46, 0.5, 0.53, 0.57, 0.6, 0.62, 0.65, 0.68, 0.7, 0.73, 0.77, 0.8, 0.84, 0.87, 0.9, 0.93, 0.96, or 0.99.

The gap between the first pixel 101 and the closer one of the two adjacent second pixels 102 has a first width value, the gap between the first pixel 101 and the farther one of the two adjacent second pixels 102 has a second width value, and the ratio of the first width value to the second width value is greater than or equal to 0.1 and is less than or equal to 1. For example, the ratio is 0.1, 0.13, 0.17, 0.2, 0.23, 0.26, 0.3, 0.34, 0.37, 0.4, 0.44, 0.46, 0.5, 0.53, 0.57, 0.6, 0.62, 0.65, 0.68, 0.7, 0.73, 0.77, 0.8, 0.84, 0.87, 0.9, 0.93, 0.96, 1.

The distance between the center B1 of the first pixel 101 and the connecting line A3 is greater than or less than the distance between the center B1 of the first pixel 101 and the connecting line A5.

Alternatively, the distance between the center B1 of the first pixel 101 and the connecting line A3 is equal to the distance between the center B1 of the first pixel 101 and the connecting line A5.

As shown in FIGS. 1 to 8, a length of the connecting line A3 is less than a length of the connecting line A5. As shown in FIG. 9 and FIG. 10, the length of the connecting line A3 is equal to the length of the connecting line A5.

The through hole is located in the portion of the anode corresponding to a non-light-emitting region, that is, the through hole is located at one side of the pixel (at the gap between the two light-emitting pixels). In the same light-emitting pixel row or the same light-emitting pixel column, the through holes of the light-emitting pixels with the same color are located on the same line. In the same light-emitting pixel row or the same light-emitting pixel column, the distance between the connecting line of the through holes corresponding to one of the first pixel 101, the second pixel 102, and the third pixel 103 and the connecting line of the through holes corresponding to another one of the first pixel 101, the second pixel 102, and the third pixel 103 is greater than 0. That is, in the same light-emitting pixel row or the same light-emitting pixel column, the connecting line of the through holes corresponding to two of the first pixels 101, the connecting line of the through holes corresponding to two of the second pixels 102, and the connecting line of the through holes corresponding to two of the third pixels 103 are not collinear with each other.

Along the row direction or the column direction, the distance between the through holes of two adjacent first pixels 101 is greater than the diameter of the through holes.

It is understandable that there are certain tolerances in the actual manufacturing process. The centers of the through holes corresponding to the light-emitting pixels with the same color may not be absolutely on the same straight line, but it can be observed that they are roughly on the same straight line as a whole. The through holes of the light-emitting pixels with another color can be observed to be located on different straight lines as a whole. Such a design corresponds to the arrangement of the light-emitting pixels, which can facilitate to design the layout of the panel, and avoid the uneven display caused by the excessive distance between the through holes and the positions of the light-emitting pixels.

The first through hole 104 is located within the coverage area of the projection of the first pixel 101 on the plane where the display panel is located, the second through hole 105 is located within the coverage area of the projection of the second pixel 102 on the plane where the display panel is located, and the third through hole 106 is located within the coverage area of the projection of the third pixel 103 on the plane where the display panel is located.

Alternatively, the first through hole 104 is located outside the coverage area of the projection of the first pixel 101 on the plane where the display panel is located, the second through hole 105 is located outside the coverage area of the projection of the second pixel 102 on the plane where the display panel is located, and the third through hole 106 is located outside the coverage area of the projection of the third pixel 103 on the plane where the display panel is located. For example, the second through hole 105 is disposed at the gap between the first pixel 101 and the second pixel 102, and the third through hole 106 is disposed at the gap between the first pixel 101 and the third pixel 103. In particular, among the two second pixels 102 and the two third pixels 103 adjacent to the first pixel 101, the through hole (the second through hole 105 or the third through hole 106) of one of the second pixel 102 and the third pixel 103 which is far away from the first pixel 101 is provided in the gap between the second pixel 102 and the third pixel 103.

The cross-sectional area, in a direction perpendicular to the current conduction direction, of the conductive member of one of the first pixel 101, the second pixel 102, and the third pixel 103 with a greater area is greater than the cross-sectional area, in a direction perpendicular to the current conduction direction, of the conductive member of one of the first pixel 101, the second pixel 102, and the third pixel 103 with a smaller area. The length of conductive member of one of the first pixel 101, the second pixel 102, and the third pixel 103 with a greater area is less than the length of the conductive member of one of the first pixel 101, the second pixel 102, and the third pixel 103 with a smaller area.

The area of the luminescent material layer of one of the first pixel 101, the second pixel 102, and the third pixel 103 which has a higher luminous efficiency is less than the area of the luminescent material layer of one of the first pixel 101, the second pixel 102, and the third pixel 103 which has a lower luminous efficiency. However, the thickness of the luminescent material layer of one of the first pixel 101, the second pixel 102, and the third pixel 103 which has a higher luminous efficiency is greater than the thickness of the luminescent material layer of one of the first pixel 101, the second pixel 102, and the third pixel 103 which has a lower luminous efficiency. The area of the luminescent material layer of the light-emitting pixel with a higher luminous efficiency is smaller, so that the luminous efficiency and the light-emitting area can be integrated, so that the lifetime of the light-emitting pixels with different colors is approximately equal. However, in practice, the lifetime of light-emitting pixels is not simply positively correlated with the luminous efficiency and the light-emitting area, and the lifetime of light-emitting pixels also is related to the thickness of the luminescent material. Through practice, the inventor finds that in the case where the area of the luminescent material layer of one of the first pixel 101, the second pixel 102, and the third pixel 103 which has a higher luminous efficiency is less than the area of the luminescent material layer of one of the first pixel 101, the second pixel 102, and the third pixel 103 which has a lower luminous efficiency, setting the thickness of the luminescent material layer of one of the first pixel 101, the second pixel 102, and the third pixel 103 which has a higher luminous efficiency to be greater than the thickness of the luminescent material layer of one of the first pixel 101, the second pixel 102, and the third pixel 103 which has a lower luminous efficiency can increase the lifetime of the display panel.

The long axis of the first pixel 101 points to one of the second pixel 102 and the third pixel 103 which has a greater area, and the short axis of the first pixel 101 points to one of the second pixel 102 and the third pixel 103 which has a smaller area. Because the curvature radius of the edge portion at the end of the long axis of the first pixel 101 which is an ellipse is smaller than the curvature radius of the edge portion at the end of the short axis of the first pixel 101, setting the ling axis of the first pixel 101 to point to one of the second pixel 102 and the third pixel 103 which has a greater area and setting the short axis of the first pixel 101 to point to one of the second pixel 102 and the third pixel 103 which has a smaller area can reduce the risk of the color mixing (cross color) of the first pixel 101 and the second pixel 102 or the third pixel 103.

In the present disclosure, the centers of the second pixels connected to the pixel-driving circuit in a same row are located in a line differing from a line in which the centers of the third pixels connected to the pixel-driving circuit in a same row are located, and/or the centers of the second pixels connected to the pixel-driving circuit in a same column are located in a line differing from a line in which the centers of the third pixels connected to the pixel-driving circuit in a same column are located; and the centers of the second through holes corresponding to the second pixels in a same row are located in a line differing from a line in which the centers of the third through holes corresponding to the third pixels in a same row are located, and/or the centers of the second through holes corresponding to the second pixels in a same column are located in a line differing from a line in which the centers of the third through holes corresponding to the third pixels in a same column are located. That is, the first through hole corresponding to the first pixel is located outside a connecting line of the second through holes corresponding to the adjacent two second pixels arranged along the first direction or the second direction, and/or the first through hole corresponding to the first pixel is located outside a connecting line of the third through holes corresponding to the adjacent two third pixels arranged along the first direction or the second direction, the center of one of the second pixels is located outside a connecting line of the centers of the adjacent two third pixels, the center of one of the third pixels is located outside a connecting line of the centers of the adjacent two second pixels. In this way, in at least one of the first direction and the second direction, at least two light-emitting pixels with different colors are arranged along a polyline instead of being arranged along a straight line, therefore, light-emitting pixels in adjacent two light-emitting pixel rows can be merged in the column direction, or light-emitting pixels in adjacent two light-emitting pixel columns can be merged in the row direction, which is beneficial to improving the display effect.

In addition, the above technical solution is beneficial to overcome the jagged feeling of the picture when displaying lines that are inclined relative to the row direction or the column direction (especially suitable for high-resolution images), and therefore, is beneficial to improve the display effect.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims,

What is claimed is:

1. A display panel, comprising:
a pixel-driving circuit arranged in an array;
a plurality of light-emitting pixels including a plurality of first pixels, a plurality of second pixels, and a plurality of third pixels; and
an insulating layer located between the pixel-driving circuit and the light-emitting pixels and provided with a plurality of first through holes, a plurality of second through holes, and a plurality of third through holes;
wherein the first pixels, the second pixels, and the third pixels are electrically connected to the pixel-driving circuit via the first through holes, the second through holes, and the third through holes, respectively;
wherein centers of the second pixels connected to the pixel-driving circuit in a same row are located in a line differing from a line in which centers of the third pixels connected to the pixel-driving circuit in a same row are located, and/or centers of the second pixels connected to the pixel-driving circuit in a same column are located in a line differing from a line in which centers of the third pixels connected to the pixel-driving circuit in a same column are located;
wherein centers of the second through holes corresponding to the second pixels in a same row are located in a line differing from a line in which centers of the third through holes corresponding to the third pixels in a same row are located, and/or centers of the second through holes corresponding to the second pixels in a same column are located in a line differing from a line in which centers of the third through holes corresponding to the third pixels in a same column are located.

2. The display panel according to claim 1, wherein a connecting line of the centers of the second through holes corresponding to the second pixels in the same row is parallel or intersecting with a connecting line of the centers of third through holes corresponding to the third pixels in the same row, and a connecting line of the centers of second holes corresponding to the second pixels in the same column is parallel or intersecting with a connecting line of the centers of third through holes corresponding to the third pixels in the same column.

3. The display panel according to claim 1, wherein, along one of a first direction and a second direction, the center of one of the second pixels is located outside a connecting line of the centers of the adjacent two third pixels, the center of one of the third pixels is located outside a connecting line of the centers of the adjacent two second pixels, the first direction is a direction in which the first pixels are repeatedly arranged, and the second direction is a direction perpendicular to the first direction;
along the other one of the first direction and the second direction, a connecting line connecting the center of one of the second pixels and the center of the adjacent one of the third pixels is parallel to the other one of the first direction and the second direction.

4. The display panel according to claim 1, wherein a shape of one of the first pixels is a rectangle, a shape of one of the second pixels is a square, a shape of one of the third pixels is a rectangle, a long edge of one of the first pixels is parallel to a long edge of one of the third pixels, and a short edge of one of the first pixels is parallel to one edge of one of the second pixels.

5. The display panel according to claim 1, wherein a shape of one of the second pixels and a shape of one of the third pixels are both trapezoids, a shape of one of the first pixels is a rectangle, a long edge of one of the first pixels is parallel to a bottom edge of one of the second pixels whose shape is the trapezoid or a bottom edge of one of the third pixels whose shape is the trapezoid, and a short edge of one of the first pixels is parallel to the bottom edge of one of the third pixels whose shape is the trapezoid or the bottom edge of one of the second pixels whose shape is the trapezoid.

6. The display panel according to claim 1, wherein a long edge of one of the first pixels is parallel to one edge of one of the second pixels whose shape is a parallelogram or one edge of one of the third pixels whose shape is a parallelogram, and a short edge of one of the first pixels is parallel to one edge of one of the third pixels whose shape is the parallelogram or one edge of one of the second pixels whose shape is the parallelogram.

7. The display panel according to claim 1, wherein a shape of one of the first pixels includes a convex arc, and a shape of one of the second pixels and a shape of one of the third pixels both include a concave arc and/or a convex arc.

8. The display panel according to claim 7, wherein a shape of one of the first pixels is a circle or an ellipse, a shape of one of the second pixels and a shape of one of the third pixels both include a plurality of concave arcs and a plurality of convex arcs, two ends of one of the convex arcs are respectively connected to two of the concave arcs, two ends of one of the concave arcs are respectively connected to two of the convex arcs, and an arc length of one of the convex arcs is less than an arc length of one of the concave arcs;
wherein the arc length of the concave arc in the second pixel is greater or less than the arc length of the concave arc in the third pixel.

9. The display panel according to claim 8, wherein one of the two second pixels adjacent to the first pixel has a curvature radius toward an edge portion of the first pixel, and the curvature radius is greater than or equal to a curvature radius of the other one of the two second pixels adjacent to the first pixel toward the edge portion of the first pixel; and
one of the two third pixels adjacent to the first pixel has a curvature radius toward the edge portion of the first pixel, and the curvature radius is greater than or equal to a curvature radius of the other one of the two third pixels adjacent to the first pixel toward the edge portion of the first pixel.

10. The display panel according to claim 7, wherein when the shape of the first pixel is an ellipse, a first included angle between a connecting line A1 connecting the centers of two of the second pixels adjacent to the first pixel and a long axis of the ellipse is greater than or equal to 0 degree, and is less than or equal to 90 degrees, and a second included angle between a connecting line A2 connecting the centers of two of the third pixels adjacent to the first pixel and the long axis of the ellipse is greater than or equal to 0 degree, and is less than or equal to 90 degrees.

11. The display panel according to claim 7, wherein a curvature radius of one of at least four concave arcs constituting the shape of the second pixel is greater than a curvature radius of another one of the four concave arcs constituting the shape of the second pixel, or a curvature radius of one of at least four concave arcs constituting the shape of the third pixel is greater than a curvature radius of another one of the four concave arcs constituting the shape of the third pixel.

12. The display panel according to claim 1, wherein a shape of one of the first pixels is a trapezoid, and a shape of one of the second pixels and a shape of one of the third pixels both include a plurality of concave arcs and/or a plurality of convex arcs.

13. The display panel according to claim 1, wherein the centers of two of the second pixels and two of the third pixels adjacent to the first pixel are four vertices of a predetermined quadrilateral, the predetermined quadrilateral at least includes a first internal angle less than or equal to 90 degrees and a second internal angle greater than or equal to 90 degrees, and the predetermined quadrilateral is a trapezoid or a parallelogram.

14. The display panel according to claim 13, wherein the angle of the first internal angle is in a range of 78 degrees to 88 degrees, and the angle of the second angle is in a range of 92 degrees to 102 degrees.

15. The display panel according to claim 1, wherein a distance E1 between a connecting line connecting the centers of two of the second pixels and a connecting line connecting the centers of two of the third pixels is less than a distance E2 between a connecting line connecting the centers of two of the first pixels and a connecting line connecting the centers of two of the second pixels.

16. The display panel according to claim 1, wherein a distance E1 between a connecting line connecting the centers of two of the second pixels and a connecting line connecting the centers of two of the third pixels is less than a distance E3 between a connecting line connecting the centers of two of the first pixels and a connecting line connecting the centers of two of the third pixels.

17. The display panel according to claim 1, wherein an intersection of a connecting line connecting the centers of two of the second pixels adjacent to the first pixel and a connecting line connecting the centers of two of the third pixels adjacent to the first pixel is located within a range enclosed by a circle, wherein the center of the first pixel is served as a center of the circle and a predetermined line segment is served as the radius of the circle.

18. The display panel according to claim 17, wherein a projection of the first pixel on a plane where the display panel is located covers the intersection.

19. The display panel according to claim 1, wherein the centers of the first pixels are located outside a connecting line connecting the centers of two of the second pixels adjacent to the first pixel and/or outside a connecting line connecting the centers of two of the third pixels adjacent to the first pixel.

20. The display panel according to claim 1, wherein a thickness of a luminescent material layer of one of the first pixel, the second pixel, and the third pixel which has a higher luminous efficiency is greater than a thickness of a luminescent material layer of one of the first pixel, the second pixel, and the third pixel which has a lower luminous efficiency.
